(19) United States
(12) Patent Application Publication
(10) Pub. No.: US 2020/0075501 A1
(43) Pub. Date: Mar. 5, 2020

(54) ELECTROMAGNETIC INTERFERENCE SHIELDING FOR SEMICONDUCTOR PACKAGES USING BOND WIRES

(71) Applicant: Intel Corporation, Santa Clara, CA (US)

(72) Inventors: Digvijay A. RAORANE, Chandler, AZ (US); Vijay K. NAIR, Mesa, AZ (US)

(21) Appl. No.: 16/070,507

(22) PCT Filed: Mar. 31, 2016
(86) PCT No.: PCT/US2016/025398

§ 371 Date: Jul. 16, 2018

(51) Int. Cl. H01L 23/552; H01L 23/13; H01L 23/49; H01L 23/498; H01L 23/00; H01L 25/065; H01L 21/48

(52) U.S. Cl. CPC H01L 23/552; H01L 23/13; H01L 23/49; H01L 23/49838; H01L 24/16; H01L 25/0657; H01L 2225/06537; H01L 21/4853; H01L 2924/3025; H01L 2224/16227; H01L 2225/06513; H01L 2225/06517; H01L 21/4889

(57) ABSTRACT

Electromagnetic interference shielding is described for a semiconductor package using bond wires. In one example, a package has a substrate having a ground plane and a top side to carry a microelectronic die, the top side further having a conductive pad coupled to the ground plane, a microelectronic die having a bottom side attached to the substrate and a top side opposite the bottom side, and a plurality of bond wires connected to the top conductive pad to form a wire mesh electromagnetic interference shield for the substrate.

### FIELD

The present description relates to semiconductor packages and in particular to interference shielding formed from bond wires around the package.

### BACKGROUND

Electromagnetic interference (EMI) can affect the operation of electronic circuitry and especially analog and radio frequency circuitry. As the carrier frequencies for wireless data increase they come closer to the operations of integrated circuits. This is a serious issue in mobile devices, such as tablets, computers and smart phones. EMI is generated within such devices and also from other nearby devices including nearby tablets, computers, and smart phones.

While EMI exists across the entire electromagnetic spectrum, from direct current electricity and frequencies less than 1 Hz to gamma rays above 1020 Hz, the great majority of

EMI problems are limited to that part of the spectrum with frequencies between 25 kHz and 10 GHz. This portion is known as the radio frequency interference (RFI) area and covers radio and audio frequencies. The acronym EMI is generally used to represent both EMI and RFI. Radio frequency interference (RFI) is also described as any undesirable electrical energy with content within the frequency range dedicated to radio frequency transmission. Radiated RFI is most often found in the frequency range from 30 MHz to 10 GHz. The interference may be transient, continuous or intermittent.

External sources of EMI include communication and radar transmitters, electric switch contacts, computers, voltage regulators, pulse generators, arc/vapor lamps, intermittent electrical ground connections, solar noise, lightening electromagnetic pulses. EMI affects the ability of high-performance electronic devices to maintain signal integrity in the time domain and to maintain power integrity in the frequency domain. For integrated circuits, the RFI frequencies are the most harmful. The electromagnetic radiation generated by one electronic RF device may negatively affect other, similar, electronic devices such as cell phones, radios, etc. When a cell phone is ON, for example, a great deal of power is transmitted. The transmitted power interferes with other devices.

EMI/RFI Shielding is used in many telecommunication devices because radio transmissions can hamper the reception of a signal if the signals RFI and the signal are near the same frequency. In addition, strong magnetic and electrical fields can affect currents and even generate currents in integrated circuits. EMI/RFI Shielding may prevent incorrect frequencies from interfering with a device. In a medical hospital, for example, equipment is shielded to allow it to meet governmental standards against being affected by cell phones, PDA's, (Personal Digital Assistants) or other electronic devices.

As the sizes of system boards, integrated circuit packages, radio dies and power supplies continue to decrease, the power density has increased and power consumption is reduced. These smaller, lower power components are even more sensitive to EMI. As a result, shielding becomes more important.

### BRIEF DESCRIPTION OF THE DRAWINGS

Embodiments are illustrated by way of example, and not by way of limitation, in the figures of the accompanying drawings in which like reference numerals refer to similar elements.

FIG. 1 is a cross-sectional side view diagram of a package with substrate with a cavity to hold one or more chips according to an embodiment.

FIG. 2 is a cross-sectional side view diagram of the package having a chip in the cavity according to an embodiment.

FIG. 3 is a cross-sectional side view diagram of the package with an EMI shield attached to the chip formed of bond wires according to an embodiment.

FIG. 4 is a top view diagram of the package with the EMI shield attached to the chip according to an embodiment.

FIGS. 5A and 5B are cross-sectional side view diagrams of packages with two chips in the cavity and bond wires over the chips according to embodiments.

FIG. 6 is a side cross-sectional side view diagram of a first fabrication stage of a package having a substrate according to an embodiment.

FIG. 7 is a cross-sectional side view diagram of a second fabrication stage of the package having an attached die on the substrate according to an embodiment.

FIG. 8 is a cross-sectional side view diagram of a third fabrication stage of a package having wire bond openings in the substrate according to an embodiment.

FIG. 9 is a cross-sectional side view diagram of a fourth fabrication stage of the package having a bond wire shield over the die according to an embodiment.

FIG. 10 is a cross-sectional side view diagram of another package having stacked dies in a package with a bond wire shield according to an embodiment.

FIG. 11 is a top view diagram of the package of FIG. 10 according to an embodiment.

FIG. 12 is a block diagram of a computing device suitable for use with embodiments.

### DETAILED DESCRIPTION

EMI/RFI shielding can greatly increase size, cost and bulk in a semiconductor package. As described herein, a shield may be formed while installing in a corresponding system board or package substrate. This reduces additional steps that otherwise would be required. As described herein a flip chip may be shielded in an installation that uses surface mount technology. In the case of a WLCSP (Wafer Level Chip Scale Package) and many other types of packages, bond wires may be used to form a shield. This may avoid a need for an additional external shield. Instead the EMI shield is built within the package installation.

The processes used to form the shield are all mature processes such as plating so that the implementation may be formed accurately and reliably. Existing packaging techniques such as flip chip packaging may also be used.

Several different ways are described herein to provide an EMI and RFI shield for flip chip and WLCSP packages. In one embodiment, a Faraday cage is prepared over a surface mount flip chip die using a Wire mesh above the die. The ground planes inside substrate are shorted across the top of the die using the mesh of bond wires. In another embodiment back side metallization on the die is used. The Faraday cage of bond wires is connected to the back side metallization on the die.

In another embodiment, a WLCSP is embedded into a cavity in the motherboard. A bond wire mesh is built above the die and cavity in the motherboard. The wires are shorted to the ground planes in the motherboard. Similarly, in another embodiment a plating layer may be used on the back side of the die and the wire mesh attached to the back side metallization of the die.

Wire bonding provides real time flexibility to change the process to accommodate each product, each die, and each motherboard. Wire bonding does not require any change in collaterals to accommodate different dies. Various parameters such as the wire mesh density and the size of the wire mesh may be changed without much difficulty. Using a motherboard cavity, the z-height may be lowered while a shield is provided over the cavity. This may substitute for an additional, external shield since the shield is built over the cavity.

As described herein mature processes such as plating and wire bonding may be used. This allows for improved reliability and yield. Existing packaging techniques such as flip chip and WLCSP may be also be used for additional reliability.

FIG. 1 is a cross-sectional side view diagram of a substrate with a cavity to hold one or more chips. The substrate 102 may be formed of silicon, pre-impregnated epoxy resin, buildup layers with alternating metal and dielectric or any other suitable type of substrate. The substrate may be used as a package substrate, chip socket, motherboard, daughterboard, system board or any other type of basic board. In the present example, the substrate represents a package substrate, however, it may alternatively represent a portion of a printed circuit board (PCB) that serves a system board for an electronic device. A cavity 114 is formed in the substrate to hold one or more chips.

In this example, the die is attached to the package substrate (also referred to as the package). The package substrate is then attached to the PCB board directly or through a socket. However, for direct chip attach, the die is attached directly to a PCB, such as a motherboard.

A ground plane 104 is formed in one or more layers of the system board. The ground plane may be part of a power plane or it may be provided only for interference suppression. The ground plane is shown as extending under the cavity, but it may be on either side of the cavity and may extend to the edges and beyond the diagram. A set of vias 106 extend through the substrate from the ground plane to the bottom of the cavity. An array of pads or lands 108 connect to the vias. These will provide an attachment point for a chip installed into the cavity. These pads provide an electrical power connection for the chip and in some embodiments may permit a shield or cover, such as back side metallization, on the chip to be grounded.

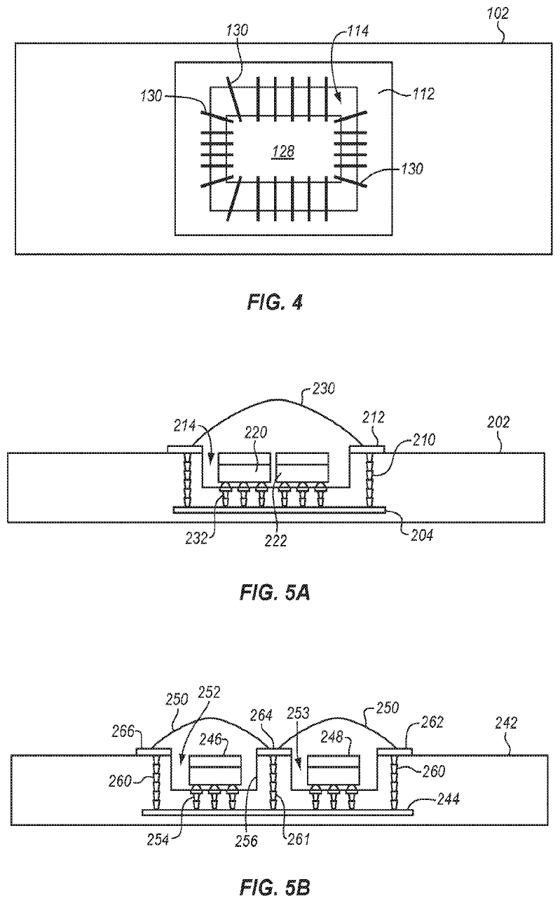

A second stack of vias 110 is formed on either side of the cavity. These side vias make a connection from the ground plane 104 to a pad 112 at the top of the PCB. The pad may be much larger and may cover all or most of the perimeter of the cavity. As shown in FIG. 4, a top view of the pad 112, the pad may be a copper layer that surrounds the cavity. This provides a convenient surface to which bond wires 130 may be attached. While only two vias are visible in this cross-sectional side view diagram, there may be multiple vias placed at distances across perimeter of the cavity. The number of vias may be selected to provide sufficient conductivity for the expected amount of EMI shielding. The vias may also be placed at regular and consistent intervals so that the vias also provide EMI shielding. A spacing that is shorter than the shortest anticipated wavelength may be used to effectively protect the die from radiation coming to or from the sides of the die 120.

For purposes of fabrication, a package substrate or PCB may be formed in a conventional way with multiple wiring layers to make power and data connections to and between the various chips that will be mounted on the substrate. The wiring layers are formed so that there is no wiring in the upper layers near a cavity. The cavity is then formed in the motherboard. It may be formed by laser ablation, etching, machining or other techniques, depending on the nature and structure of the PCB. Stacked vias are formed along what will become or already is the edge of cavity. The bottom end of the stack of vias is attached to the ground plane or planes in the substrate. The plated region 112 forms a pad on the top of the substrate that is attached to the substrate to form the EMI shield for the die. For a substrate that is formed of buildup layers, the vias may be formed as the buildup layers are created. In some embodiments, the cavity may be formed as the substrate buildup layers are applied.

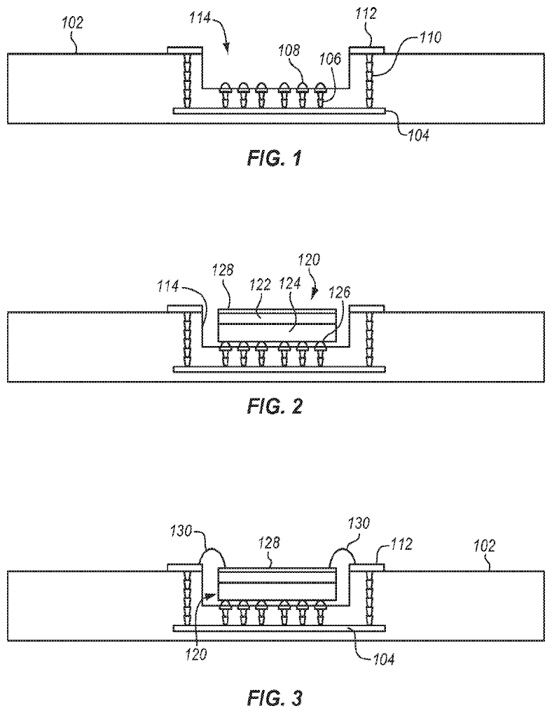

FIG. 2 is a cross-sectional side view diagram showing the substrate 102 of FIG. 1 with a chip 120 installed into the cavity 114. The die is formed on a suitable substrate 122. A metal layer 128 is applied over one side of the die and a dielectric layer 124 is applied over the other side of the die. An array of conductive bumps, pads, lands, solder balls or other suitable structure 126 is formed over the dielectric layer and electrically connects to the pads 108 in the cavity.

The chip may take many different forms and the connections to the substrate or system board inside the cavity may be made in a variety of different ways. For a flip chip, such as a WLCSP, the substrate has a back side facing up in the diagram of FIG. 2. The metal layer is plated over the back side of the substrate. Active circuitry has been formed on the front side of the substrate. The active circuitry includes an array of lands for power and data connections. The dielectric layer 124 is formed over these lands in multiple alternating metal and dielectric layers. Vias through these metal and dielectric layers connect the connection pads 126 to the active circuitry. Other chips may have other structures. The top metal layer may be on the front side or the back side.

FIG. 3 is a cross-sectional side view diagram of the chip installed into the cavity with wire bonds connecting the ground plane of the substrate to the metal layer on the die. FIG. 4 is a top plane view diagram of the structure of FIG. 3. As in FIGS. 1 and 2, FIGS. 3 and 4 show a package substrate or may be viewed for other embodiments as only a small portion of a system board. The components are not drawn to scale in order to better show the details of the various embodiments. The bond wires 130 are connected between the metal layer 128 on the top side of the chip 120 and the grounded pad 112 on the top of the substrate around the cavity 114. The bond wires 130 may be installed in a tight mesh pattern to form a radio frequency shield. The pattern of spacing and positioning of the wires may be adapted to suit the size of the chip and the cavity and frequencies and amplitudes that are to be shielded.

The structure of FIGS. 3 and 4 is well suited for use as a flip chip EMI shield in which a Faraday cage is prepared using wire mesh above the chip and the wires are shorted to ground planes inside the PCB substrate. In this example, the wires are shorted to a back side metallization layer, such as a plating layer, on the die. The Faraday cage is formed of a wire mesh of bond wires attached to the back side of die. In another variation, the wire mesh is over the die and does not contact the flip chip at all. In this embodiment, the flip chip may include a back side metallization or no metallization layer. An example of such an approach is shown in FIGS. 5, 10 and 11.

FIGS. 1 to 4 may be understood as fabrication stages for producing a package as described herein. FIG. 5 shows a variation of the last fabrication stage of FIG. 4. Accordingly, FIG. 1 shows forming a substrate with a ground plane, a connector array to attach to die, and a top side conductive pad coupled to the ground plane. FIG. 2 shows attaching a die to the connector array and FIG. 3 shows attaching bond wires to the top conductive pad to form a wire mesh electromagnetic interference shield for the substrate.

FIGS. 3 and 4 show one approach to attaching the bond wires. FIG. 5 shows another way of attaching the bond wires. In the example of FIG. 3, the die is a flip chip die with a front side attached to the connector array of the substrate and a back side having a metal layer. The bond wires are attached with one end attached to the conductive pad and the other end attached to the back side metal layer.

FIG. 5 shows a variation in which the top conductive pad 212 is on each of the four sides of the die or dies 220, 222. The bond are then attached to each extend over the dies each from one side of the die to an opposite side the die and are orthogonally arranged to form the wire mesh. In this way they act as a Faraday cage over the die. The bond wires are separated by a distance smaller than an anticipated wavelength of electromagnetic interference.

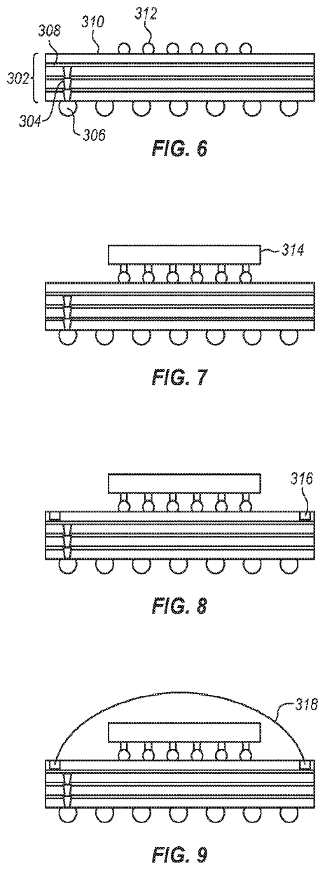

FIG. 1 also shows optional operation of forming a cavity in the substrate. FIGS. 6 to 9 show fabrication stages in which there is no cavity formed in the substrate. A connector array is then formed in the cavity and the die is attached to the connector array within the cavity.

FIG. 5A is a cross-sectional side view diagram of a modification of the shielded chip of FIG. 5 in which the bond wires extend across the cavity. In this example, a PCB or other substrate 202 used as a system board or package substrate and has a cavity 214. Two different chips 220, 222 are mounted side-by-side within the cavity. There may be more or fewer than two chips. They may be of any desired type. In this example, the chips are flip chips attached using surface mount technology with an array of connection pads on each chip soldered to pads on the substrate. For two chips with no EMI between them no shield is needed between them.

Side vias 210 are formed in the substrate 202 and extend from a ground plane 204 to a pad 212 at the top of the system board. The ground plane may be at a lower layer and extend under the cavity as shown. Alternatively, the ground plane may be at a higher layer and stop before the walls of the cavity.

The top grounded pad 212 is on several sides or even around the entire perimeter of the cavity as shown in FIG. 4 or FIG. 11. However, the bond wires 230 do not stretch from the pads to the chips but from the pad on one side of the cavity to the pad on the other side of the cavity. The wire mesh formed by the bond wires 230 may have a configuration similar to that of FIG. 4 but stretching across the cavity as in FIG. 11. In some embodiments, the EMI shield is completed by wire bonding the plated portion 212 of motherboard 202 over the back sides of both dies. In this embodiment, no back side metallization for the chips is needed.

In some embodiments the flip chips are WLCSP placed and attached inside the cavity of the motherboard. An EMI shield is formed also by the stacked vias 210 around the cavity, the ground planes 204 in the substrate, and the wire bonding 230 across the cavity. The shielding may be increased in some embodiments by grounding one or both of the dies. Vias 232 from the bottom of the cavity 214 may be used to electrically connect a contact pad on the chip to the ground plane. One or both of the chips may also have a grounded back side metallization layer on the top surface. While the chips may be flip chips with the back side facing upward and the front side connected through vias to the bottom of the cavity, any of a variety of other chip configurations may alternatively be used.

In some embodiments, a flip chip die is provided with an EMI shield using a standard package. A radio frequency die or another type of die may be packaged using an otherwise standard flip chip package. An EMI shield may then be constructed around the die using any desired configuration. The shield may be constructed using wire bonding which is flexible and mature process. This allows many different shield shapes and configurations to be used.

In some embodiments, there may be EMI or electromagnetic coupling between the dies in the package. FIG. 5B is a side cross-sectional diagram similar to FIG. 5A. In a smart phone or computer, there may be a wireless network chip and another RFIC, such as a cellular radio chip. These may be placed very close together for quick communication through the substrate but shielded from each other as well. FIG. 5B shows a package with two cavities 252, 253 separated by a wall 256 of the substrate. Each cavity has one or more chips 246, 248, connected using vias 254 through the substrate to a ground plane 244 and to any other wiring layers of the substrate as desired. There are conductive pads 262, 266 on either side of the two chips and also a pad 264 between the chips on the wall of substrate 256 between them. The conductive pads are coupled with vias 260, 261 to the ground plane and bond wires 250 are connected to the conductive pads as in FIGS. 3 and 5A. In this embodiment, the bond wires are connected over each cavity separately to each cover only a single cavity and chip. As a result, the cavities are isolated from each other by the bond wires and by the vias 261 in the wall between the chips.

Referring to FIG. 6 a flip chip package substrate 302 is built with special adaptations for an EMI shield. FIG. 6 is a cross-sectional side view diagram of a package substrate with adaptations for supporting an EMI shield. The package substrate may be formed of any suitable package substrate material including prepreg and buildup layers. The package has multiple ground layers 308 that are shorted along the edge of the package substrate using stacked vias 304. The package substrate has a bottom ball grid, land grid, solder ball, or other appropriate connection array 306 to attach to a socket, system board, or other connection system. The vias connect the ground planes 308 to an external ground through at least one of these balls or lands 308.

The top of the substrate is covered in a dielectric 310 and an array 312 of connectors to receive a die. The connectors connect through vias (not shown) to redistribution and connection layers (not shown) in the substrate to external connections through the bottom connection array 306.

FIG. 7 is a cross-sectional side view diagram of the package substrate of FIG. 6 with an attached die 314. The die is placed on the package and then attached with surface mount technology, solder reflow or some other approach. The die may be of any desired type and there may be multiple dies that are stacked or mounted side-by-side.

FIG. 8 is a cross-sectional side view diagram of the package substrate of FIG. 7 with optional connection holes 316 formed in the package substrate 302. The top dielectric layer 310 may be ablated to expose the ground plane 308 within the package. The top dielectric layer 310 may be formed of solder resist which is particularly well suited to precise removal by ablation and other processes. Alternatively the openings may be formed during the fabrication of the substrate before attaching the die. However, flip chip place and attach processes may cause a pre-existing hole to be contaminated. Alternatively, vias may connect from the ground plane to pads on the top surface of the substrate as in FIG. 1.

Each hole is used to attach one end of a bond wire to the ground layer. The other end will then be attached to another hole on the other opposite side of the die. Two holes are visible in this cross-sectional view which is enough for one wire 318 as shown in the cross-sectional side view diagram of the completed package of FIG. 9. The die will not have a single bond wire but will be enclosed inside a dome of wire mesh formed by bonding many wires in wire bonding processes, similar to that of FIG. 11. The number and spacing of the wires are determined based on product requirements. The most significant requirement is the wavelengths of EMI from which die is to be shielded. Accordingly, there may be multiple holes on each side and on the two opposing sides that are not visible in this diagram.

In another embodiment, the die 314 has a back side metallization layer 128 as in FIG. 3 and the bond wires connect each from a hole to the metallization layer. In this embodiment, as in FIG. 3, the metal layer provides an EMI shield for the back side of the die and the bond wires 318 provide a shield for the sides of the die.

The described wire mesh shields are particularly well suited for integrating radio frequency or any other EMI generating devices into a flip chip or WLCSP package. The described shielding may be added at low cost and with very little extra required space. An EMI shield cage may be made of a mesh of bond wires that are grounded through stacked vias to ground planes in a system board or package substrate and connected to a back side metallization on a flip chip or WLCSP that is mounted to a cavity in the motherboard

In another embodiment an EMI shield cage may be made of a mesh of bond wires that are coupled at both ends to grounded stacked vias connected to ground planes in a system board or package substrate. The flip chip or WLCSP is mounted to the cavity in the motherboard covered by the wire bonding scheme across the cavity. In another embodiment, the flip chip or WLCSP is mounted on a top surface of the motherboard without being enclosed in a cavity. In another embodiment, the flip chip or WLCSP is mounted on a top surface of a package substrate without being enclosed in a cavity to later be mounted to a motherboard through the package substrate.

The approaches described herein are particularly suitable for adding shielding to any FC (Flip Chip) package, WLCSP or similar type of package. This allows sensitive devices within the package or outside of the package to be protected. As described herein, an EMI cage is formed using stacked via and ground planes in a WLCSP or similar package.

EMI shielding as described herein may be useful in embedded die architectures in communication and similar types of devices for which EMI is a major concern. Different chips may be mounted closer to one another because the as EMI imposed by one chip on another would be lower. When done thoroughly, no additional shielding or Faraday's cage may be required.

The back side metallization 114, 332, 334, 406 may be plated to the back side of the die using metal particles dispersed in organic or aqueous liquids. Such coatings may also be applied using spray painting. In some embodiments, a thick coating of more than 25 μm thick may be used with the metal particles that are on the orders of a few pm thick.

For a reduced z-height for the package, a thinner coating, such as an electroless coating may be used. Various metals such as Ag, Cu. Au, Al, Zn, Ni, Sn may be used as a shielding material. Various combinations of metal layers may also be used, for example 250 nm of Ni over 1000 nm of Cu. The specific combination and thicknesses of layers may be selected based on the expected amplitude and frequencies of interference that is to be shielded.

In order to provide a shielding effectiveness greater than about 40 dB the metallization and via systems described herein may be combined with additional external shielding or more complex multiple layer coatings may be used. Depending on the implementation even very thin electroless coatings may be sufficient for the desired EMI shielding.

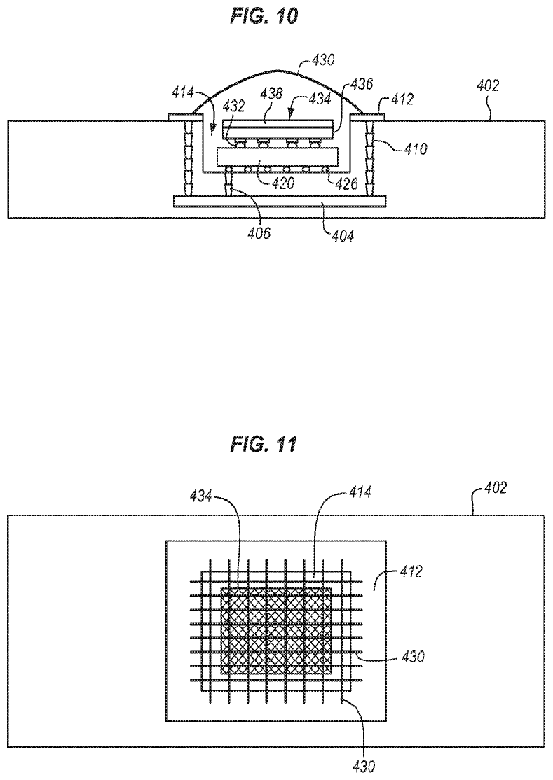

FIG. 10 is a cross-sectional side view diagram of a stacked die in a cavity of a package substrate or PCB in which the bond wires extend across the cavity. In this example, a PCB or other substrate 502 is used as a system board or package substrate and has a cavity 514. Two different chips 420, 434 are mounted stacked on top of each other within the cavity. There may be more or fewer than two chips. Additional chips may be placed beside these chips as in FIG. 5. In this example, the chips are flip chip attached using surface mount technology. The first chip is attached to the pads on the bottom of the cavity with appropriate solder bumps 426. The top chip is attached face down to the back side of the bottom chip with solder bumps 432. The back side of the bottom chip has an array of pads and vias provided to make this connection. Other types of connection structures such as wire leads, interposers, etc. may be used instead or in addition to the stacked configuration as shown.

Side vias 410 in the substrate 402 extend from the ground plane 404 to a top pad 412 at the top of the substrate. The top pad is the attachment surface for a mesh of bond wires 430 as in the example of FIG. 5 and may surround the cavity in whole or in part as in FIG. 11. The bond wire mesh stretches across the cavity as in FIG. 11 to provide an EMI shield. In this embodiment, no back side metallization for the chips is needed, however, the back side of one or both of the chips may have a grounded metal layer to provide additional or different interference protection depending on the implementation.

FIG. 11 is a top view diagram of the package of FIG. 10 in which the substrate 402 has a top connective pad 412 surrounding the cavity 414. The mesh 430 of bond wires covers the die 434 from the top and the side vias 410 (not shown) within the substrate protect the sides of the die.

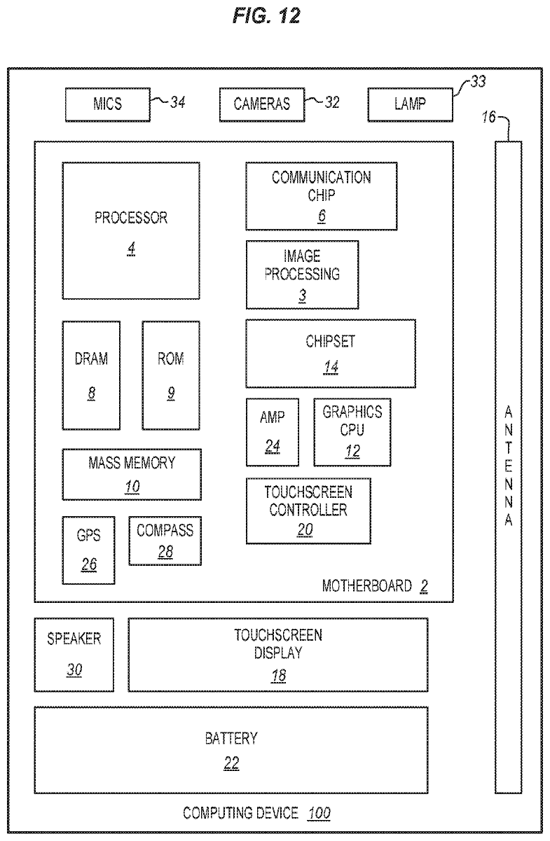

FIG. 12 illustrates a computing device 100 in accordance with one implementation. The computing device 100 houses a board 2. The board 2 may include a number of components, including but not limited to a processor 4 and at least one communication chip 6. The processor 4 is physically and electrically coupled to the board 2. In some implementations the at least one communication chip 6 is also physically and electrically coupled to the board 2. In further implementations, the communication chip 6 is part of the processor 4.

Depending on its applications, computing device 100 may include other components that may or may not be physically and electrically coupled to the board 2. These other components include, but are not limited to, volatile memory (e.g., DRAM) 8, non-volatile memory (e.g., ROM) 9, flash memory (not shown), a graphics processor 12, a digital signal processor (not shown), a crypto processor (not shown), a chipset 14, an antenna 16, a display 18 such as a touchscreen display, a touchscreen controller 20, a haptic actuator array 21, a battery 22, an audio codec (not shown), a video codec (not shown), a power amplifier 24, a global positioning system (GPS) device 26, a compass 28, an accelerometer (not shown), a gyroscope (not shown), a speaker 30, a camera 32, and a mass storage device (such as hard disk drive) 10, compact disk (CD) (not shown), digital versatile disk (DVD) (not shown), and so forth). These components may be connected to the system board 2, mounted to the system board, or combined with any of the other components.

The communication chip 6 enables wireless and/or wired communications for the transfer of data to and from the computing device 100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 6 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 100 may include a plurality of communication chips 6. For instance, a first communication chip 6 may be dedicated to shorter range wireless communications such as Wi-Fi and Bluetooth and a second communication chip 6 may be dedicated to longer range wireless communications such as GPS, EDGE, GPRS, CDMA, WiMAX, LTE, Ev-DO, and others.

The processor 4 of the computing device 100 includes an integrated circuit die packaged within the processor 4. In some implementations, the packages that include the processor, memory devices, communication devices, or other components may include interference shielding and connections as described herein, if desired. The term “processor” may refer to any device or portion of a device that processes electronic data from registers and/or memory to transform that electronic data into other electronic data that may be stored in registers and/or memory.

In various implementations, the computing device 100 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, a digital video recorder, wearables, and drones. In further implementations, the computing device 100 may be any other electronic device that processes data.

Embodiments may be adapted to be used with a variety of different types of packages for different implementations. References to “one embodiment”, “an embodiment”, “example embodiment”, “various embodiments”, etc., indicate that the embodiment(s) so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, the specific location of elements as shown and described herein may be changed and are not limited to what is shown. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to an apparatus that includes a substrate having a ground plane and a top side to carry a microelectronic die, the top side further having a conductive pad coupled to the ground plane, a microelectronic die having a bottom side attached to the substrate and a top side opposite the bottom side; and a plurality of bond wires connected to the top conductive pad to form a wire mesh electromagnetic interference shield for the substrate.

In further embodiments the die is rectangular, wherein the top conductive pad is on each of the four sides of the die, and wherein the bond wires each extend over the top side of the die each from one side of the die to an opposite side the die.

In further embodiments the bond wires are orthogonally arranged to form the wire mesh and to act as a Faraday cage over the die.

In further embodiments the bond wires are separated by a distance smaller than an anticipated wavelength of electromagnetic interference.

In further embodiments the substrate has a connector array to electrically connect to the die, wherein the connector array is within a cavity in the substrate, and wherein the conductive pad is not in the cavity so that the conductive pad is above the top side of the die.

Further embodiments include a second microelectronic die stacked over the first die within the cavity and wherein the bond wires are also over the second microelectronic die.

In further embodiments the pads are formed by an embedded wiring layer of the substrate that is exposed from the top surface of the substrate by ablating a dielectric layer of the substrate.

In further embodiments the top side of the die is the back side, the die further comprising a back side metallization layer and wherein the bond wires are each coupled to the top conductive pad at one end and to the back side metallization at the other end.

In further embodiments the die has a front side coupled to the connector array and wherein the back side metallization is coupled to the ground plane through the front side of the die and the connector array.

In further embodiments the substrate has a connector array to electrically connect to the die, wherein the connector array is within a cavity in the substrate, wherein the conductive pad is not in the cavity so that the conductive pad is above the top side of the die, wherein the top side of the die is the back side, the die further comprising a back side metallization layer and wherein the bond wires are each coupled to the top conductive pad at one end and to the back side metallization at the other end.

Further embodiments include a second microelectronic die beside the first die within the cavity and wherein the bond wires are also over the second microelectronic die.

In further embodiments the bond wires are connected to each other through the ground plane.

In further embodiments the die is coupled to the ground plane through the substrate.

Some embodiments pertain to a method that includes forming a substrate with a ground plane, a connector array to attach to die, and a top side conductive pad coupled to the ground plane, attaching a die to the connector array, and attaching a plurality of bond wires to the top conductive pad to form a wire mesh electromagnetic interference shield for the substrate.

Further embodiments include forming a cavity in the substrate and forming the connector array in the cavity and wherein attaching the die comprises attaching the die to the connector array within the cavity.

In further embodiments the die is a flip chip die with a front side attached to the connector array and a back side having a metal layer and wherein attaching a plurality of bond wires comprises attaching the bond wires with one end attached to the conductive pad and the other end attached to the back side metal layer.

In further embodiments the top conductive pad is on each of the four sides of the die, wherein the bond wires each extend over the die each from one side of the die to an opposite side the die and are orthogonally arranged to form the wire mesh and to act as a Faraday cage over the die, and wherein the bond wires are separated by a distance smaller than an anticipated wavelength of electromagnetic interference.

Some embodiments pertain to a computing system that includes a printed circuit board, a memory attached to the printed circuit board, and a package attached to the printed circuit board, the package having a substrate having a ground plane and a top side to carry a microelectronic die, the top side further having a conductive pad coupled to the ground plane, a microelectronic die having a bottom side attached to the substrate and a top side opposite the bottom side, and a plurality of bond wires connected to the top conductive pad to form a wire mesh electromagnetic interference shield for the substrate.

In further embodiments the printed circuit board has a ground plane, wherein the ground plane of the substrate is connected to the ground plane of the printed circuit board, and wherein the die is coupled to the ground plane of the substrate through the substrate.

In further embodiments the substrate has a cavity, wherein the die is surface mounted to a bottom surface of the cavity, wherein the die has a back side metal layer opposite the bottom of the cavity, and wherein the bond wires are attached at one end to the conductive pad and at the other end to the back side metal layer.

1. An apparatus comprising:
a substrate having a ground plane and a top side to carry a microelectronic die, the top side further having a conductive pad coupled to the ground plane;
a microelectronic die having a bottom side attached to the substrate and a top side opposite the bottom side; and
a plurality of bond wires connected to the top conductive pad to form a wire mesh electromagnetic interference shield for the substrate.

2. The apparatus of claim 1, wherein the die is rectangular, wherein the top conductive pad is on each of the four sides of the die, and wherein the bond wires each extend over the top side of the die each from one side of the die to an opposite side of the die.

3. The apparatus of claim 2, wherein the bond wires are orthogonally arranged to form the wire mesh and to act as a Faraday cage over the die.

4. The apparatus of claim 3, wherein the bond wires are separated by a distance smaller than an anticipated wavelength of electromagnetic interference.

5. The apparatus of claim 2, wherein the substrate has a connector array to electrically connect to the die, wherein the connector array is within a cavity in the substrate, and wherein the conductive pad is not in the cavity so that the conductive pad is above the top side of the die.

6. The apparatus of claim 5, further comprising a second microelectronic die stacked over the first die within the cavity and wherein the bond wires are also over the second microelectronic die.

7. The apparatus of claim 1, wherein the pads are formed by an embedded wiring layer of the substrate that is exposed from the top surface of the substrate by ablating a dielectric layer of the substrate.

8. The apparatus of claim 7, wherein the top side of the die is the back side, the die further comprising a back side metallization layer and wherein the bond wires are each coupled to the top conductive pad at one end and to the back side metallization at the other end.

9. The apparatus of claim 8, wherein the die has a front side coupled to the connector array and wherein the back side metallization is coupled to the ground plane through the front side of the die and the connector array.

10. The apparatus of claim 1, wherein the substrate has a connector array to electrically connect to the die, wherein the connector array is within a cavity in the substrate, wherein the conductive pad is not in the cavity so that the conductive pad is above the top side of the die, wherein the top side of the die is the back side, the die further comprising a back side metallization layer and wherein the bond wires are each coupled to the top conductive pad at one end and to the back side metallization at the other end.

11. The apparatus of claim 10, further comprising a second microelectronic die beside the first die within the cavity and wherein the bond wires are also over the second microelectronic die.

12. The apparatus of claim 5, further comprising a second microelectronic die within the cavity, wherein the cavity has a wall and a conductive pad on the wall between the first die and the second die and wherein the bond wires form a first wire mesh over the first die and a second wire mesh over the second die to isolate interference between the first die and the second die.

13. The apparatus of claim 1, wherein the die is coupled to the ground plane through the substrate.

14. A method comprising:
forming a substrate with a ground plane, a connector array to attach to die, and a top side conductive pad coupled to the ground plane;
attaching a die to the connector array; and
attaching a plurality of bond wires to the top conductive pad to form a wire mesh electromagnetic interference shield for the substrate.

15. The method of claim 14, further comprising forming a cavity in the substrate and forming the connector array in the cavity and wherein attaching the die comprises attaching the die to the connector array within the cavity.

16. The method of claim 15, wherein the die is a flip chip die with a front side attached to the connector array and a back side having a metal layer and wherein attaching a plurality of bond wires comprises attaching the bond wires with one end attached to the conductive pad and the other end attached to the back side metal layer.

17. The method of claim 15, wherein the top conductive pad is on each of the four sides of the die, wherein the bond wires each extend over the die each from one side of the die to an opposite side the die and are orthogonally arranged to form the wire mesh and to act as a Faraday cage over the die, and wherein the bond wires are separated by a distance smaller than an anticipated wavelength of electromagnetic interference.

18. A computing system comprising:
a printed circuit board;
a memory attached to the printed circuit board; and
a package attached to the printed circuit board, the package having a substrate having a ground plane and a top side to carry a microelectronic die, the top side further having a conductive pad coupled to the ground plane, a microelectronic die having a bottom side attached to the substrate and a top side opposite the bottom side, and a plurality of bond wires connected to the top conductive pad to form a wire mesh electromagnetic interference shield for the substrate.

19. The computing system of claim 18, wherein the printed circuit board has a ground plane, wherein the ground plane of the substrate is connected to the ground plane of the printed circuit board, and wherein the die is coupled to the ground plane of the substrate through the substrate.

20. The computing system of claim 18, wherein the substrate has a cavity, wherein the die is surface mounted to a bottom surface of the cavity, wherein the die has a back side metal layer opposite the bottom of the cavity, and wherein the bond wires are attached at one end to the conductive pad and at the other end to the back side metal layer.
